(19) United States
(12) Patent Application Publication
(10) Pub. No.: US 2025/0346996 A1
(43) Pub. Date: Nov. 13, 2025

(54) Temperature Cycling Method for Atomic Layer Deposition on High-Aspect-Ratio and High-Surface-Area Substrates

(71) Applicant: The Government of the United States of America, as represented by the Secretary of the Navy, Arlington, VA (US)

(72) Inventors: Benjamin L. Greenberg, Washington, DC (US); Boris N. Feigelson, Springfield, VA (US); Kevin P. Anderson, Annandale, VA (US); Alan G. Jacobs, Rockville, MD (US); James A. Wollmershauser, Alexandria, VA (US)

(73) Assignee: The Government of the United States of America, as represented by the Secretary of the Navy, Arlington, VA (US)

(21) Appl. No.: 18/660,364

(22) Filed: May 10, 2024

(51) Int. Cl. C23C 16/455

(52) U.S. Cl. CPC C23C 16/45527; C23C 16/45553

(57) ABSTRACT

A method for coating high-aspect-ratio (HAR) and high-surface-area (HSA) substrates via atomic layer deposition (ALD) wherein the temperature of the substrate is varied cyclically during the ALD process. An exemplary temperature schedule for each ALD cycle includes at least one predetermined lower temperature during a diffusion/reaction stage of the cycle, where the lower temperature prevents decomposition of the ALD precursors and further prevents other side reactions, and further includes at least one predetermined higher temperature during a purge stage of the cycle, where the higher temperature enables rapid purging of excess precursor and/or byproducts produced during the reaction stage of the cycle. The prevention of side reactions ensures that the ALD coating is uniform and has the desired composition with minimal impurities, and the rapid purging ensures reasonable total process time.

### CROSS-REFERENCE

This Application is a Nonprovisional of and claims the benefit of priority under 35 U.S.C. § 119 based on U.S. Provisional Patent Application No. 63/501,312 filed on May 10, 2023. The Provisional Application and all references cited herein are hereby incorporated by reference into the present disclosure in their entirety.

### FEDERALLY-SPONSORED RESEARCH AND DEVELOPMENT

The United States Government has ownership rights in this invention. Licensing inquiries may be directed to Office of Technology Transfer, US Naval Research Laboratory, Code 1004, Washington, DC 20375, USA; +1.202.767.7230; nrltechtran@us.navy.mil, referencing Navy Case #211592.

### TECHNICAL FIELD

The present invention relates to the field of high-aspect-ratio and high-surface-area substrates such as nanoparticle compacts, aerogels, or metalorganic frameworks and provides a method for atomic layer deposition of coatings such as oxides, nitrides, chalcogenides, halides, or metals on such substrates.

### BACKGROUND

Coating the surfaces of high-aspect-ratio (HAR) and high-surface-area (HSA) substrates with oxides, nitrides, metals, or other materials via atomic layer deposition (ALD) can be a highly effective approach to tuning their thermal, electronic, optical, chemical, and other properties.

In such cases, HAR or HSA substrates are coated via ALD from precursors that may include organometallic compounds such as trimethylaluminum (TMA) or diethylzinc (DEZ) and oxidants such as water or ozone. The ALD process is cyclic, with each cycle consisting of doses of precursor vapor or gas separated by intervening purge steps, with the total coating mass being controlled via the number of ALD cycles. Coating of HAR or HSA substrates is achieved via larger precursor exposures (higher precursor partial pressure and/or longer duration) and longer purges relative to those used to coat conventional planar substrates.

In principle, the ALD deposition reactions are self-limiting, and so uniform deposition on all surfaces of the substrate can be achieved via sufficiently large reactant exposures.

The precursor exposures required for HAR and HSA substrates can be much greater than those used for conventional flat low-SA substrates. For example, uniform deposition of an Al₂O₃ coating throughout the internal surface of a silica aerogel monolith with AR>60,000 has been achieved using trimethylaluminum (TMA) precursor exposures>10⁴ Torr-s, six orders of magnitude greater than doses often used for ALD of Al₂O₃ on wafers. See Gayle, A. J. et al., Tunable Atomic Layer Deposition into Ultra-High-Aspect-Ratio (>60000:1) Aerogel Monoliths Enabled by Transport Modeling. Chem. Mater. 33, 5572-5583 (2021).

For a highly stable reactant such as TMA, such large doses are generally unproblematic, and the ALD chemistry is essentially unaffected.

For many other ALD processes based on less-stable reactants, however, long dose times can lead to significant precursor decomposition and other undesirable non-self-limiting side reactions, leading to poor coating uniformity and high impurity content.

Examples of important ALD coatings that are derived from reactants that have relatively low thermal stability—and thus are susceptible to degradation at large doses-include insulating titanium oxide (TiO₂), semiconducting zinc oxide (ZnO), and metallic gold (Au). See Maeng, W. J., et al., Thermal and Plasma-Enhanced ALD of Ta and Ti Oxide Thin Films from Alkylamide Precursors. Electrochem. Solid-State Lett. 9, G191 (2006); Ferguson, J. D., et al., Surface chemistry and infrared absorbance changes during ZnO atomic layer deposition on ZrO₂ and BaTiO₃ particles. J. Vac. Sci. Technol. Vac. Surf. Films 23, 118-125 (2005); Ingale, P. et al., Atomic Layer Deposition of ZnO on Mesoporous Silica: Insights into Growth Behavior of ZnO via In-Situ Thermogravimetric Analysis. Nanomaterials 10, 981 (2020); and Griffiths, M. B. E., et al., Atomic Layer Deposition of Gold Metal. Chem. Mater. 28, 44-46 (2016).

ALD of ZnO from the reactants diethylzinc (DEZ) and water provides an illustrative example of a useful process that is difficult to scale up for HAR or HSA substrates. This ALD process has been used to enhance the electrical conductivity of relatively low-AR (˜10²) nanoparticle thin films. See Greenberg, B. L. et al., Metal-insulator transition in a semiconductor nanocrystal network. Sci. Adv. 5, eaaw 1462 (2019); and Lanigan, D. et al., Contact Radius and the Insulator-Metal Transition in Films Comprised of Touching Semiconductor Nanocrystals. ACS Nano 10, 6744-6752 (2016). Scaling up to nanoparticle compacts with AR>10³ or nanopowders with SA>10 m²/g is necessary for a variety of existing and envisioned applications of ZnO-containing nanocomposites, including in optoelectronics, catalysis, and medicine.

Large DEZ exposures, however, have been shown to compromise coating purity. At an ALD temperature of 177° C., Ferguson et al. increased DEZ exposure up to 900 Torr-s to deposit ZnO on ZrO₂ nanoparticle (NP) powder with SA=20.2 m²/g, and they observed evidence of non-self-limiting metallic Zn deposition, which they attributed to DEZ decomposition. See Ferguson et al., supra.

At temperatures ranging from 150 to 200° C., Libera et al. used a DEZ exposure of ˜20 Torr-s to coat silica gel powder with SA=100 m²/g, and they observed metallic Zn deposition at 155° C. and above but not at 150° C. See Libera, J. A. et al., Conformal ZnO coatings on high surface area silica gel using atomic layer deposition. Thin Solid Films 516 (2008) 6158-6166. Based on experimental data, see Yousfi, E. B. et al., Study of atomic layer epitaxy of zinc oxide by in-situ quartz crystal microgravimetry. Appl. Surf. Sci. 153, 223-234 (2000), and density functional theory calculations, Weckman and Laasonen argued that significant formation of bare Zn on the coating surface, a precursor to metallic Zn deposition, occurs at 140° C. and above. See Weckman, T. et al., Atomic Layer Deposition of Zinc Oxide: Diethyl Zinc Reactions and Surface Saturation from First-Principles. J. Phys. Chem. C 120, 21460-21471 (2016); and Weckman, T. et al., Atomic Layer Deposition of Zinc Oxide: Study on the Water Pulse Reactions from First-Principles. J. Phys. Chem. C 122, 7685-7694 (2018).

While this result suggests that pure ZnO could be obtained at any DEZ exposure by reducing the temperature below 140° C., the application of this strategy to deposition of electrically conductive ZnO coatings on HAR or HSA substrates is complicated by two factors.

First, for deposition temperatures below ˜170° C., the conductivity of ALD-grown ZnO often decreases with temperature due to changes in stoichiometry, grain size, and orientation. See Sang, B. S. B. et al., Growth of Transparent Conductive Oxide ZnO Films by Atomic Layer Deposition. Jpn. J. Appl. Phys. 35, L602 (1996); and Tynell, T. et al., Atomic layer deposition of ZnO: a review. Semicond. Sci. Technol. 29, 043001 (2014).

Second, the purge time after each H₂O dose required to remove enough residual H₂O to prevent nonuniform deposition increases exponentially with decreasing temperature, which can lead to impractical ALD process times.

For example, the purge time required for sufficient removal of H₂O from an Al₂O₃ substrate for uniform ALD on the substrate is ˜3 min at 177° C., but ˜73 min at 137° C. See Cendejas, A., et al., Modeling atomic layer deposition process parameters to achieve dense nanocrystal-based nanocomposites. J. Vac. Sci. Technol. A 39, 012406 (2020). For a typical ALD run consisting of 100 cycles (the number of cycles required to produce a ˜20 nm ZnO coating, see Tynell et al., supra), the latter purge time translates to ˜120 hrs spent on post-H₂O purges alone.

Consequently, there is a need for an ALD method for coating HAR and HSA substrates such that (1) typical ALD reactants can be employed in the process regardless of thermal stability, (2) the resultant coatings are uniform, pure, and have the same properties as equivalent coatings on conventional substrates, and (3) relatively short purge times can be used—e.g., <10 min—so that the total ALD process time is reasonable.

### SUMMARY

This summary is intended to introduce, in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

The present invention provides a method for coating high-aspect-ratio (HAR) and high-surface-area (HSA) substrates via atomic layer deposition (ALD) wherein the temperature of the substrate is varied cyclically during the ALD process. In accordance with the present invention, the temperature schedule for each ALD cycle includes at least one predetermined lower temperature during a diffusion/reaction stage of the cycle, where the lower temperature prevents decomposition of the ALD precursors and further prevents other side reactions during one part of the cycle and at least one predetermined higher temperature during a purge stage of the cycle, where the higher temperature enables rapid purging of excess precursor and/or byproducts produced during the reaction stage of the cycle. The prevention of side reactions ensures that the ALD coating is uniform and has the desired composition with minimal impurities, and the rapid purging ensures reasonable total process time.

### BRIEF DESCRIPTION OF THE DRAWINGS

FIGS. 1A and 1B are block schematics illustrating the deposition temperature schedules used for atomic layer deposition in the prior art (FIG. 1A) and in accordance with the present invention (FIG. 1B).

FIG. 2 is a block schematic illustrating aspects of a single cycle in a temperature-cycled method for atomic layer deposition in accordance with the present invention.

FIG. 3 is a block schematic illustrating an exemplary substrate setup for a nanoparticle compact used in a temperature-cycled method for atomic layer deposition into the substrate in accordance with the present invention.

FIGS. 4A and 4B are ALD chamber pressure and deposition temperature plots further illustrating aspects of an exemplary implementation of a temperature-cycled method for atomic layer deposition of ZnO in accordance with the present invention.

FIGS. 5A-5C illustrate results of exemplary application of constant temperature (FIGS. 6A and 6B) and cycled temperature (FIG. 6C) during atomic layer deposition of ZnO on a high-aspect-ratio substrate.

FIG. 6 is a plot showing X-ray diffraction patterns of ZnO-coated Al₂O₃ nanoparticle compacts with the substrate temperature T held at 120° C., T held at 160° C., and T cycled between 120° C. and 160° C. in accordance with the present invention.

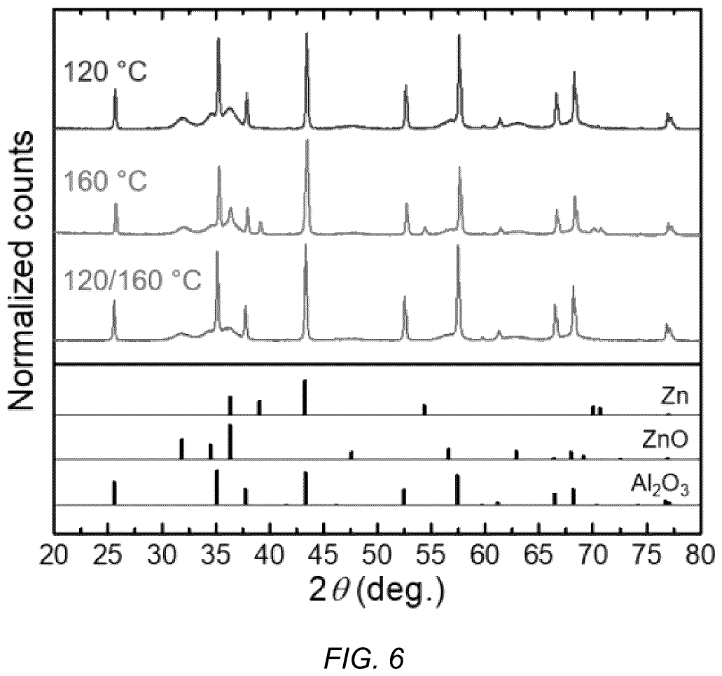

### DETAILED DESCRIPTION

The aspects and features of the present invention summarized above can be embodied in various forms. The following description shows, by way of illustration, combinations and configurations in which the aspects and features can be put into practice. It is understood that the described aspects, features, and/or embodiments are merely examples, and that one skilled in the art may utilize other aspects, features, and/or embodiments or make structural and functional modifications without departing from the scope of the present disclosure.

As described in more detail below, the present invention provides a method for coating high-aspect-ratio (HAR) and high-surface-area (HSA) substrates via atomic layer deposition (ALD) wherein the temperature of the substrate is varied cyclically during the ALD process to provide an ALD coating that is uniform and has the desired composition with minimal impurities within a reasonable total process time.

The HAR and HSA substrates may include, but are not limited to, powders (e.g., nanoparticles, zeolites, metal-organic-frameworks) or solids (e.g., nanoporous solids, solids with deep and narrow trenches). The ALD process may be any ALD process in which the temperature required for rapid removal of excess precursor and/or byproducts during purging is a temperature at which side reactions are significant. The substrate temperature may be controlled via heating of the ALD chamber and/or direct heating of the substrate, either or both which can be accomplished via any method compatible with the ALD process, including resistive heating and photonic heating.

As used herein, the term “high-aspect-ratio (HAR) substrate” refers to any substrate having a large ratio of its largest dimension to its smallest dimension such that long ALD precursor doses are required for infiltration into the substrate. The term “high-surface-area (HSA) substrate” refers to any substrate with a large total surface area such that large ALD precursor exposures are required to coat the surface completely. For example, a macroscopic nanoporous solid may be described as both HAR and HSA, while a nanoparticle thin film may be described as HAR only, and a nanopowder may be described as HSA only.

As used herein, the term “dose” and “dosing” refers to a stage of an ALD process in which an ALD precursor gas or vapor is intentionally delivered to the substrate's reactive surface sites. The term “exposure” refers to the integral, with respect to time, of the ALD precursor gas or vapor pressure during a dose, typically approximated as the product of time and an average pressure. The term “reaction period” refers to the timespan during which reactions involving a particular ALD precursor or its derivatives can occur; this includes the dose of the precursor as well as the purge step immediately following that dose, during which reactions may continue due to the presence of residual precursor gas/vapor, precursor molecules adsorbed on the substrate's surface, and/or reactive or unstable surface species produced by deposition reactions between the precursor and the substrate.

As described above, ALD is a cyclical process for coating a substrate in which each cycle consists of precursor doses separated by intervening purges. High-aspect-ratio (HAR) and high-surface-area (HSA) substrates can be coated uniformly via ALD with sufficiently large doses and long purges.

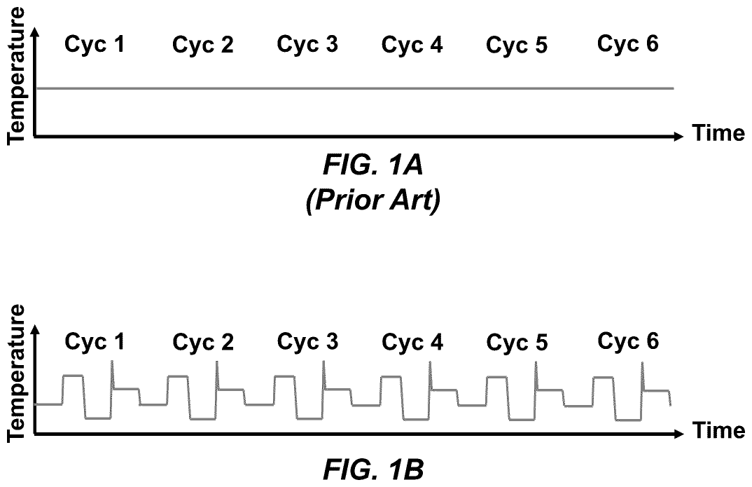

Prior art methods for ALD of coatings such as oxides, nitrides, and metals on HAR and/or HSA substrates have done so using a pre-selected constant processing temperature that generally lies within the “ALD window,” i.e., the temperature range in which the ALD process is well-behaved when used to coat conventional planar substrates, throughout all of the deposition cycles, as illustrated by the block schematic in FIG. 1A. However, as noted above, use of such constant temperatures in ALD on HAR and HSA substrates can lead to precursor decomposition and other side reactions during the reaction periods, resulting in impure and/or nonuinform coatings, or slow removal of byproducts during purges, resulting in impractically long process times. Some prior art methods for ALD on conventional flat low-SA substrates have employed cyclically varied substrate temperatures. See, e.g., U.S. Pat. No. 7,442,415 to Conley et al., entitled “Modulated Temperature Method of Atomic Layer Deposition (ALD) of High Dielectric Constant Films”; see also Piercy, B. D. et al., Pulsed heating atomic layer deposition (PH-ALD) for epitaxial growth of zinc oxide thin films on c-plane sapphire, Dalton Trans. 51, 303 (2022). These methods, however, were not applied to HAR or HSA substrates, and the purpose of cyclically elevating the temperature was to alter the deposited coating properties (e.g., to induce crystallization) rather than to expedite purging or to activate the deposition reaction as in the present invention.

The present invention solves these problems by providing a method for coating such HAR and HSA substrates via ALD wherein the temperature of the substrate is varied cyclically during the ALD process, as illustrated by the block schematic in FIG. 1B.

As described in more detail below, an ALD coating can be formed on an HAR or HSA substrate by means of a process that includes the following steps (a) through (f):
(a) placing the substrate in a reaction chamber;
(b) in a first dosing step D1, applying a predetermined dose of a first ALD precursor to the substrate at a first predetermined substrate temperature TDI for a first predetermined duration t_{P1} to diffuse the first ALD precursor into the substrate and react the first ALD precursor with all available interior and exterior surfaces of the substrate;
(c) in a first purge step P1, applying a second predetermined temperature T_{P1} to the substrate for a second predetermined duration t_{P1} to purge the substrate and deposition chamber of unreacted first ALD precursor and reaction byproducts;
(d) following the first purge step P1, in a second dosing step D2, applying a predetermined dose of a second ALD precursor to the substrate at a third predetermined substrate temperature T_{D2} for a third predetermined duration t_{P2} to diffuse the second ALD precursor into the substrate and react with all available interior and exterior surfaces of the substrate;
(e) following the second dosing step D2, in a second purge step P2, applying a fourth predetermined temperature T_{P2} to the substrate for a fourth predetermined duration t_{P2} to purge the substrate and deposition chamber of unreacted second ALD precursor and reaction byproducts;
   wherein at least one of T_{D1}, T_{P1}, T_{D2}, and T_{P2} is different from at least one other of T_{D1}, T_{P1}, T_{D2}, and T_{P2}; and
(f) repeating steps (b)-(e) until an ALD coating having a predetermined thickness is formed on the substrate.

In some embodiments, the number N of precursors for the ALD coating is greater than two. In such embodiments, a dose step Dᵢ and a purge step Pᵢ for each ith precursor can be conducted at a predetermined temperatures T_{Di} and T_{Pi} for a predetermined duration t_{Di} and t_{Pi}.

In some embodiments, the process can further include an additional step during any dosing step Dᵢ, wherein at a predetermined time during the dosing step Dᵢ the temperature of the substrate is raised to a predetermined temperature T′_{Di}>T_{Di} for a predetermined duration t′_{Di}<t_{Di}, to react the ith ALD precursor with the substrate.

Thus, as illustrated in FIG. 1B and as described in more detail below, in accordance with the present invention, the temperature schedule for each ALD cycle includes at least one predetermined first temperature TD during a diffusion/reaction stage of the cycle, where the first temperature T_{D} prevents decomposition of the ALD precursors and further prevents other side reactions during one part of the cycle and at least one predetermined second temperature T_{P} during a purge stage of the cycle, where the second temperature T_{P} enables rapid purging of excess precursor and/or byproducts produced during the reaction stage of the cycle. The prevention of side reactions ensures that the ALD coating is uniform and has the desired composition with minimal impurities, and the rapid purging ensures reasonable total process time.

In many embodiments, during each diffusion/purge cycle, T_{P} is higher than T_{D}, but other relative temperature regimes may be used as appropriate.

In some cases, heating the substrate to a higher temperature during an ALD cycle may lead to undesirable modification of the ALD film, and this modification can be countered or ameliorated during the ALD process. For example, a high-temperature purge step may cause deoxygenation of a metal oxide ALD film, and this can be minimized by maintaining sufficient oxygen gas pressure in the ALD chamber during the purge step.

In some embodiments, one or more precursor doses each can be conducted at two or more temperatures, with the temperature being held at a lower value while the precursor diffuses into the substrate, then being rapidly ramped to one or more higher values to facilitate the deposition reaction, and then rapidly lowered. Such a temperature profile, with minimal times at each of the higher temperatures, may be necessitated by a substrate/coating materials system in which a non-self-limiting reaction occurs between one of the precursors and the substrate; i.e., the short time at high temperature may ensure that the desired deposition reaction occurs with minimal occurrence of the undesired non-self-limiting reaction.

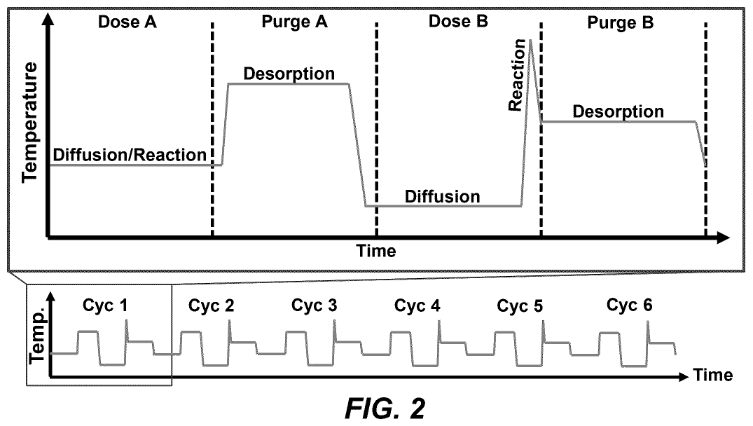

The block schematic in FIG. 2 illustrates the temperature cycling method for ALD on a substrate in accordance with the present invention, and provides further detail regarding the temperature schedules in a single cycle in accordance with the method of the invention.

As illustrated in FIG. 2, in an exemplary ALD process consisting of 2 precursors (A and B) and 6 cycles, the deposition occurs in a series of cycles where in each cycle, the temperature is varied for each step in the cycle, with the temperature returning to its initial value at the end of one cycle and the beginning of the next. This cyclical process continues until the deposition is completed.

Thus, as illustrated in FIG. 2, in an exemplary cycle, identified as “Cyc 1,” Doses A and B (the doses of precursors A and B) occur at a lower temperatures than Purges A and B, respectively, in order to prevent the occurrence of side reactions during the doses while maintaining rapid rates of removal of the precursors and/or any byproducts during the purges. In addition, as illustrated in FIG. 2, in some cases, one or more dose (e.g., Dose B in this exemplary case) can occur at two temperatures, such that the temperature is relatively low while the precursor diffuses into the substrate, is rapidly ramped to a higher value to facilitate the deposition reaction, and then is lowered again prior to the purge portion of the cycle. Such a temperature profile, with minimal time at high temperature, may be necessitated by a substrate/coating materials system in which a non-self-limiting or otherwise undesirable reaction occurs between precursor B and the substrate; i.e., the short time at high temperature may ensure that the desired deposition reaction occurs with minimal occurrence of the undesirable reaction. For an example of such an undesirable reaction that may occur in the case aluminum oxide ALD on a zinc oxide substrate, see Zywotko, D. R. and George, S. M., Thermal Atomic Layer Etching of ZnO by a “Conversion-Etch” Mechanism Using Sequential Exposures of Hydrogen Fluoride and Trimethylaluminum, Chem Mater. 29, 1183-1191 (2017).

The method of the present invention produces uniform and pure coatings on HAR and HSA substrates and prevents ALD precursor decomposition, uncontrolled CVD, and other side reactions while maintaining a reasonable total process time.

### Example

The advantages of a temperature-cycled ALD process for depositing a coating on high-AR and high-SA substrates can be demonstrated by the following Example in which ZnO was deposited in a nanoparticle compact by means of temperature-cycled ALD in accordance with the present invention. See Greenberg, B. L. et al., Conformal coating of macroscopic nanoparticle compacts with ZnO via atomic layer deposition, J. Vac. Sci. Technol. A 42, 012402 (2024).

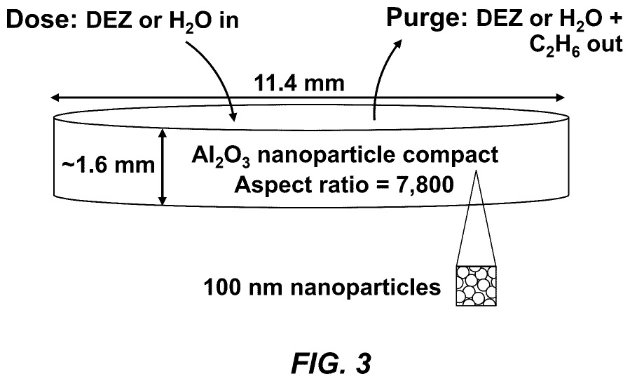

FIG. 3 illustrates an exemplary substrate setup for such deposition. However, one skilled in the art will readily understand that the configuration shown in FIG. 3 is merely exemplary, and that other configurations can be used to accomplish the method of the present invention.

In this Example, an Al₂O₃ nanoparticle compact having a diameter of 11.4 mm, a half-thickness L=0.78 nm, nanoparticle diameter d_{NP}=100 nm, and aspect ratio AR=7,800 was positioned in a reaction chamber so that both the top and bottom surfaces of the compact were exposed to the reactants and a ZnO coating was formed on the compact by ALD.

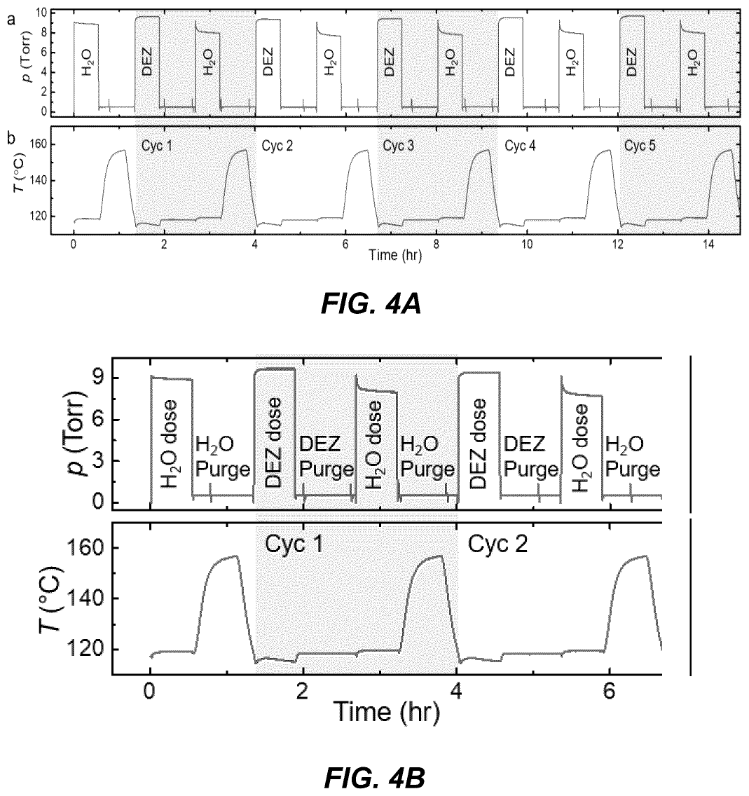

To form the ZnO coating on the compact, 20 cycles of ALD were performed to deposit the ZnO onto all available interior and exterior surfaces of the compact using DEZ and H₂O as precursors. During each dose cycle, the ALD chamber was filled to ˜9 Torr with a precursor, and then the precursor was held in the chamber for 32 minutes to allow time for the precursor to diffuse into the substrate and react with all available surfaces. As shown by FIG. 4A and in more detail in FIG. 4B, during each ALD cycle, the deposition temperature T was maintained at 120° C. for all steps except for the post-H₂O-dose purge, during which it was ramped up to 160° C. and then lowered back down to 120° C. before the subsequent DEZ dose. The higher T during the H₂O purge ensured reasonably rapid desorption and removal of H₂O, while the lower T during all other steps prevented undesired side reactions. In addition, as shown in FIGS. 4A and 4B, the chamber pressure was increased during the DEZ hold and decreased during the H₂O hold, which in both cases indicates progress in the diffusion-reaction process.

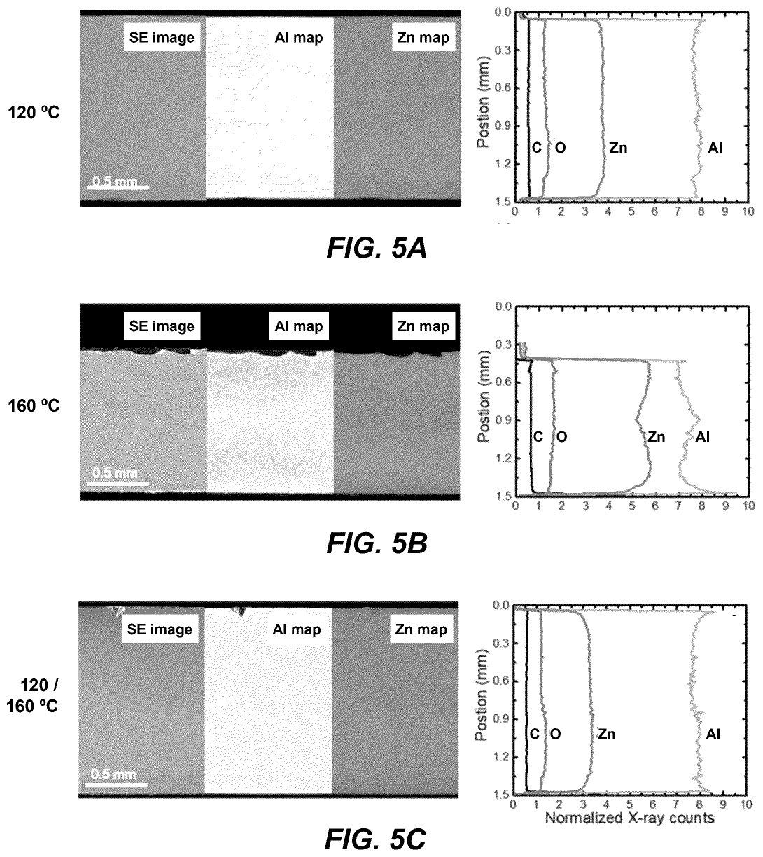

The results of this temperature-cycled deposition are illustrated in FIGS. 5A-5C, which show cross-sectional scanning electron microscopy with energy-dispersive spectroscopy (SEM-EDS) and X-ray diffraction plots of ZnO-coated Al₂O₃ nanoparticle compacts, where FIGS. 5A and 5B show the SEM images, Al kα maps, and Zn kα maps and corresponding Al kα, Zn kα, O ka, and C ka line scans for the case where the deposition temperature was held at 120° C. and 160° C., respectively, and FIG. 5C shows the result where the temperature was cycled between 12° and 160° C. in accordance with the present invention.

As can be seen from a comparison of these FIGURES, only the temperature-cycled process (FIG. 5C) produces a Zn concentration depth profile that is consistent with both rapid H₂O and OH removal during purges and side reaction suppression during DEZ doses.

In the 120° C. sample shown in FIG. 5A, the Zn ka signal qualitatively follows the same pattern but the counts are 12% higher, which is corroborated by a 8% higher fractional mass gain of the nanoparticle compacts. The higher Zn counts and mass gain suggest that significant residual H₂O and/or OH was present after the 120° C. purges and that this H₂O and/or OH reacted with DEZ during the DEZ doses, leading to additional ZnO deposition. While deposition uniformity was not affected in this trial, residual-H₂O-enhanced deposition can lead to nonuniformity as the coating thickness is increased. See Cendejas et al., supra.

In the 160° C. sample shown in FIG. 5B, ZnO deposition is clearly less uniform, with the Zn ka signal dipping near the center of the nanoparticle compact cross-section.

In contrast, in the 120/160° C. sample shown in FIG. 5C, aside from some Zn depletion within ˜0.2 mm of the top and bottom surfaces (which may be ameliorated by reducing the post-DEZ purge time), the normalized Zn ka signal is essentially constant throughout the thicknesses, indicating uniform ZnO deposition on the substrate surfaces.

This nonuniform Zn ka profile of the 160° C. sample is consistent with non-self-limiting metallic Zn deposition. Indeed, X-ray diffraction patterns of the nanoparticle compacts shown in FIG. 7 (which also shows reference powder diffraction patterns for Al₂O₃ (corundum), ZnO (zincite), and metallic Zn) reveal metallic Zn in addition to ZnO in the T=160° C. sample, whereas only ZnO is detected in the T=120° C. and 120/160° C. samples. Overall these results suggest that the temperature-cycled 120/160° C. ALD process successfully minimizes both residual-H₂O-enhanced deposition and metallic Zn deposition and is capable of producing uniform (regardless of coating thickness) and pure ZnO coatings. The purge time in this process can be reduced to <10 min by increasing the purge temperature and ramp rate.

### Advantages and New Features

As described herein, the present invention provides a method for ALD of coatings such as oxides, nitrides, chalcogenides, halides, or metals onto high-aspect-ratio and high-surface-area-substrates, such as nanoparticle compacts, aerogels, or metalorganic frameworks, that provides a uniform and pure coating, which enables control over the optical, electronic, thermal, mechanical, and other properties of the resulting nanocomposites.

The approach of the present invention is highly flexible and can be applied to any ALD material, regardless of the ALD temperature window, ALD precursor stability, and aspect ratio or surface area of the substrate.

By using the temperature-cycled method in accordance with the present invention, such coatings can be obtained by means of a commercially viable processing time that is much shorter than that needed for conventional constant-temperature methods, e.g., deposition of a typical ˜5 nm coating in tens of hours vs. the hundreds of hours required by the prior art.

The cyclical temperature schedule may include any number of different temperatures, ramp rates, and hold times. For example, in an ALD process based on N precursors with each cycle consisting of N dose steps and N purge steps, a unique temperature may be assigned to each step for a total of 2N temperatures. Also, up to N different heating rates, N different cooling rates, and N different hold times may be used over the course of the cycle. Additionally or alternatively, any number of different temperatures, ramp rates, and hold times may be used within a step. For example, during a dose step, the temperature may be held at a relatively low value, T₁, while a precursor is diffusing into the HAR or HSA substrate, and then it may be rapidly increased to a higher value, T₂, at the end of the dose in order to promote the deposition reaction. In cases where a minimum temperature, Tₘᵢₙ, is required for the deposition reaction to produce the desired coating, T₁ may be lower than Tₘᵢₙ provided that T₂ is higher than Tₘᵢₙ. For long doses, such a temperature profile may be required to minimize undesired side-reactions that may occur at temperatures greater than Tₘᵢₙ, such as decomposition of the precursor or non-self-limiting reactions between the precursor and the substrate.

Although particular embodiments, aspects, and features have been described and illustrated, one skilled in the art would readily appreciate that the invention described herein is not limited to only those embodiments, aspects, and features but also contemplates any and all modifications and alternative embodiments that are within the spirit and scope of the underlying invention described and claimed herein. The present application contemplates any and all modifications within the spirit and scope of the underlying invention described and claimed herein, and all such modifications and alternative embodiments are deemed to be within the scope and spirit of the present disclosure.

What is claimed is:

1. A method for forming an atomic layer deposition (ALD) coating on a substrate, comprising:
(a) placing the substrate in a reaction chamber;
(b) in a first dosing step D1, applying a predetermined dose of a first ALD precursor to the substrate at a first predetermined temperature T_{D1} for a first predetermined duration t_{D1} to diffuse the first ALD precursor into the substrate and react the first ALD precursor with all available interior and exterior surfaces of the substrate;
(c) in a first purge step P1, applying a second predetermined temperature Tpi to the substrate for a second predetermined duration t_{P1} to purge the substrate and deposition chamber of unreacted first ALD precursor and reaction byproducts;
(d) following the first purge step P1, in a second dosing step D2, applying a predetermined dose of a second ALD precursor to the substrate at a third predetermined temperature T_{D2} for a third predetermined duration t_{P2} to diffuse the second ALD precursor into the substrate and react with all available interior and exterior surfaces of the substrate;
(e) following the second dosing step D2, in a second purge step P2, applying a fourth predetermined temperature T_{P2} to the substrate for a fourth predetermined duration t_{P2} to purge the substrate and deposition chamber of unreacted second ALD precursor and reaction byproducts;
wherein at least one of T_{D1}, T_{P1}, T_{D2}, and T_{P2} is different from at least one other of T_{D1}, T_{P1}, T_{D2}, and T_{P2}; and
(f) repeating steps (b)-(e) until an ALD coating having a predetermined thickness is formed on the substrate.

2. The method according to claim 1, wherein a number N of the ALD precursors is greater than two, and wherein a dose step Dᵢ and a purge step Pᵢ for each ith precursor is conducted at predetermined substrate temperatures T_{Di} and T_{Di} for predetermined durations t_{Di} and t_{Pi}.

3. The method according to claim 2, further comprising the following additional step during any dosing step Dᵢ:
at a predetermined time during the dosing step Dᵢ raising the temperature of the substrate to a predetermined temperature T′Dᵢ>T_{Di} for a predetermined duration t′_{Di}<t_{Di}, to react the ith ALD precursor with the substrate.

4. The method according to claim 1, wherein the substrate comprises a high-aspect-ratio (HAR) substrate.

5. The method according to claim 1, wherein the substrate comprises a high-surface-area (HSA) substrate.

6. The method according to claim 1, wherein the substrate comprises a nanoparticle compact.

7. The method according to claim 1, wherein the substrate comprises nanoparticles, aerogels, zeolites, or metal-organic-frameworks.

8. The method according to claim 1, wherein the substrate comprises a nanoporous solid or a solid with deep and narrow trenches.

9. The method according to claim 1, wherein the ALD coating comprises an oxide, a nitride, a chalcogenide, a halide, or a metallic coating.

10. The method according to claim 1, wherein the ALD coating comprises ZnO, the first ALD precursor comprises H₂O, and the second ALD precursor comprises DEZ.

11. The method according to claim 10, wherein the substrate temperature is varied between 12° and 160° C.
